(19) United States
(12) Patent Application Publication
(10) Pub. No.: US 2011/0233756 A1
(43) Pub. Date: Sep. 29, 2011

(54) WAFER LEVEL PACKAGING WITH HEAT DISSIPATION

(75) Inventors: VIREN KHANDEKAR, FLOWER MOUND, TX (US); ARKADII SAMOILOV, SARATOGA, CA (US); DUANE WILCOXEN, DALLAS, TX (US); RICKY AGRAWAL, IRVING, TX (US)

(73) Assignee: MAXIM INTEGRATED PRODUCTS, INC., SUNNYVALE, CA (US)

(21) Appl. No.: 12/730,747

(22) Filed: Mar. 24, 2010

(51) Int. Cl. H01L 23/34; H01L 21/50

(52) U.S. Cl. 257/712; 438/113; 257/E23.08; 257/E21.499

(57) ABSTRACT

A heat dissipating wafer level package and method for manufacturing a heat dissipating wafer level package is provided. The heat dissipating wafer level package has a thermally conductive coating integrated thereon which facilitates the dissipation of heat from a device into the surrounding air and/or the thermal transfer of heat away from the device toward a heat spreader or heat sink. Additionally, the coating enhances the structural integrity and strength of the wafer during the manufacturing process as well as the resulting WLP.

### CROSS-REFERENCE TO RELATED APPLICATIONS

N/A

### TECHNICAL FIELD

Embodiments of the invention relate generally to wafer level packaging (WLP). More specifically, invention embodiments are directed toward wafer level packages (WLPs) comprising a backside laminate or film, which includes thermally conducting fillers or fibers that, instead of insulating the top surface of a WLP, aid in the dissipation of heat via convection or the transfer of heat from the surface of a WLP to a heat sink.

### BACKGROUND

FIG. 1 depicts a prior art flip-chip package device 100. The flip-chip package device has a silicon die 102, which is flipped over such that the integrated circuit side or lower side of the silicon die 102 is connected to a package 104 via a plurality or an array of solder balls 106. The overall flip-chip package device 100 is then placed via the connections 108 onto a PC board (not shown).

Initially, the back side or the top side of the silicon die 102 was left bare with nothing placed thereon. With nothing on the back side of the silicon die 102, the flip-chip package 104 had a heat dissipation capability of up to about 20 watts. Over time, the flip-chip packaging technology evolved to provide a 50 to about 90 watt heat dissipation rating. This was done by incorporating a thermal interface material (TIM) 110 on the top surface of the silicon die 102. The thermal interface material is a grease, paste or silicon gel that has heat conductive qualities therein. The TIM 110 is not an adhesive and does not provide any structural enhancement to the prior art flip-chip package 100. On top of the TIM 110 was placed a heat spreader or lid 112 that sandwiched the TIM 110 between the top side of the die 102 and the bottom surface of the heat spreader 112. This prior art flip-chip configuration is seen more clearly in the expanded view of area 114. It is important to understand that the addition of the TIM 110 and the heat spreader 112 is manufactured on a piece-wise basis such that each individual die 102, after being cut from a wafer and flip-chip mounted on the package 104, is then processed one-by-one to include the placement of the TIM 110 on its upper surface along with the incorporation of a heat spreader 112 thereon.

The heat spreader or heat sink 112 may be made of aluminum or copper. The TIM 110 was used to minimize the thermal resistance between the top side of the silicon die 102 and the heat spreader 112. The combination of the heat spreader 112 and the TIM 110 help increase the thermal capabilities of the prior art flip-chip packages 100.

The TIM 110 is essentially thermal grease, jelly or silicon substance that is placed on the surface of the silicon die 102 and spreads out when the heat spreader or heat sink is pressed on as well as when heated. The TIM 110 increases the thermal conductivity between the silicon die 102 and the heat spreader 112. The TIM 110 is not used to hold the heat spreader 112 in place, but other means such as clips or silicon glue around the edges of the heat spreader (not specifically shown) are used to hold a heat spreader in place on prior art flip-chip packages.

One of the key drawbacks of flip-chip packaging is the manufacturing cost. Flip-chip package manufacturing is performed at the unit level thus; there are no economies of scale that are traditionally associated with a wafer level processing process. For example, each wafer may have a thousand or more dies manufactured thereon, but with flip-chip packaging each die must be cut from the wafer and individually packaged on a per-unit basis. Therefore, if there are a thousand dies incorporated in a wafer, the flip-chip packaging process would be required to be performed one thousand times; 1 time for each die. Therefore, what is needed is a device and manufacturing technique for making such a device that allows for manufacturing a complex silicon die with a multitude of electrical connections while still being able to dissipate more than 20 watts. It would be a further advantage if such a device could be manufactured at a wafer level rather than a per-unit level.

Prior art WLP packages may include a laminate on the back or inactive side of the WLP. The prior art laminate consists of a polymeric film with silica fillers and a heat curable adhesive on one side of the polymeric film. The polymeric film/adhesive combination provides a good surface for marking the part number or other information. The prior art polymeric film/adhesive combination acts as an insulative layer that limits thermal conductivity away from the prior art WLP packages. An insulative layer may be OK for low power WLP packages (less than about 20 watts), but it limits WLP devices from incorporating higher power circuitry (25 to 50 to about 90 watts) and larger WLP device sizes from 9×9 solder ball arrays to 20×20 arrays.

Thus, what is further needed is a WLP configuration that is conductive to aiding thermal heat removal such that higher power and larger WLP devices can be made available via an economic manufacturing process.

### SUMMARY

In an embodiment, a method of manufacturing a heat dissipating wafer level package (WLP) is provided. The method of manufacturing the heat dissipating WLP comprises a step of applying a thermally conductive coating on a back surface or inactive surface of a wafer, wherein the wafer comprises a plurality of wafer level package device sections. The method of manufacturing the heat dissipating WLP further comprises curing the thermally conductive coating that has been applied to the back surface or inactive surface of the wafer. In some embodiments, the step of applying the thermally conductive coating further comprises applying a laminate to the back surface of the wafer. An exemplary laminate may comprise a thermally conductive adhesive layer and a thermally conductive film layer. In other embodiments, the step of applying the thermally conductive coating may comprise spraying, sputtering or coating the thermally conductive coating or layer onto the back surface of the wafer.

In additional embodiments the method of manufacturing the heat dissipating wafer level package may further include dicing the wafer into a plurality of wafer level package device sections such that each wafer level package device section is an individual heat dissipating wafer level package.

Another embodiment of the invention comprises a heat dissipating WLP device. The heat dissipating WLP device comprises a WLP die, which has a circuit side and a back side. Covering the back side of the WLP die is a thermally conductive coating that comprises a thermally conductive filler that is dispersed in the coating. In some embodiments, the coating comprises a film, which includes the thermally conductive filler. In other embodiments, the thermally conductive coating comprises a thermally conductive filler that is in a mesh, woven, lattice, or non-woven configuration. Additionally, embodiments of the invention may comprise a thermally conductive coating that is an impressionably compliant thermally conductive coating adapted to conform to a surface of an item, such as a heat sink, pressed thereon.

In other embodiments, a heat dissipating WLP device is provided that comprises a WLP die which has a circuit side and a back side. The embodiment further comprises a coating that covers the back side of the WLP die. Dispersed within the coating are thermally conductive fillers. The heat dissipating WLP further includes a heat sink or heat spreader that has a first surface that is thermally engaged and attached to the top surface of the coating such that the coating is sandwiched between the back side of the WLP die and the heat sink or heat spreader.

### BRIEF DESCRIPTION OF THE DRAWINGS

For a more complete understanding, reference is now made to the following description taken in conjunction with the accompanying Drawings in which:

FIG. 1 illustrates a prior art flip-chip package;

FIG. 2 illustrates an embodiment of an exemplary wafer level package (WLP) configuration;

FIG. 3 illustrates an exemplary thermally conductive layer;

FIG. 4 illustrates a flow chart of an exemplary method of manufacturing an exemplary WLP device;

FIG. 5 illustrates an exemplary manufactured wafer in cross section; and

FIG. 6 illustrates an embodiment of an exemplary WLP device incorporating a heat spreader or heat sink.

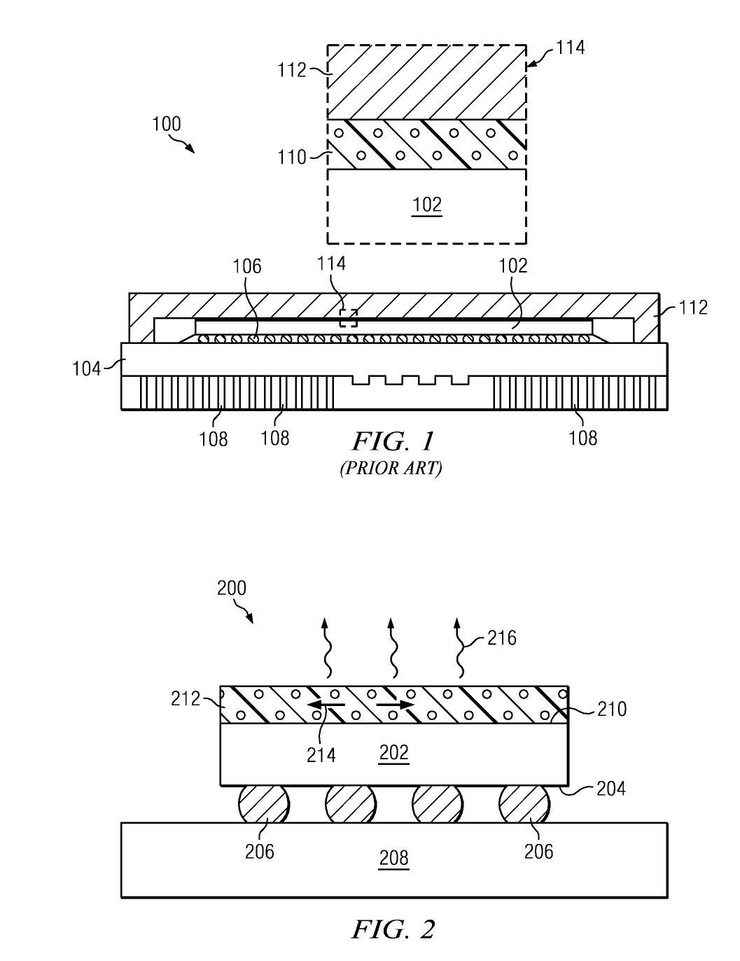

### DETAILED DESCRIPTION

Referring now to the drawings, wherein like reference numbers are used herein to designate like elements throughout, the various views and embodiments of a wafer level package incorporating heat dissipation are illustrated and described, and other possible embodiments are described. The figures are not necessarily drawn to scale, and in some instances the drawings have been exaggerated and/or simplified in places for illustrative purposes only. One of ordinary skill in the art will appreciate the many possible applications and variations based on the following examples of possible embodiments.

Embodiments of the present invention enhance the thermal performance of wafer level package (WLP) devices by incorporating into an exemplary WLP device elements and materials that provide effective heat spreading and heat dissipation about and away from an exemplary WLP device. Such heat spreading and dissipation, in accordance with embodiments of the invention, will move heat away from circuit hot-spots on exemplary WLP packages and also aid in transferring heat away from exemplary WLP packages via attached heat spreader or heat sink elements. Embodiments of the invention include a WLP with a back side laminate, layer or coating that incorporates thermally conductive fillers or fibers. The back side laminate comprising thermally conductive fillers effectively helps to spread and dissipate heat away from hot spots in an exemplary WLP and/or away from an exemplary WLP. An exemplary back side laminate with thermally conductive fillers does not insulate or provide a thermally insulative coating over the top surface (back side surface) of an exemplary WLP.

Referring now to FIG. 2, an exemplary WLP device 200 is depicted. The exemplary WLP device 200 comprises a die 202 that has an active surface 204. The active surface 204 is the side of the die with integrated circuitry embedded therein via a manufacturing process. Solder balls 206 are attached to the circuitry contained on the active side of the die 204. The solder balls 206 are used to mechanically and electrically connect an exemplary WLP device 200 to other circuitry on a PC board 208.

On the inactive or back side surface 210 of the die 202 a thermally conductive coating 212 is bonded thereon. In exemplary embodiments, the thermally conductive coating 212 completely covers the inactive or back side surface 210 of an exemplary WLP device 200. In some embodiments, the thermally conductive coating comprises a thermally conductive film. The thermally conductive film includes thermally conductive fillers or fibers. The thermal conductivity of the thermally conductive coating 212 moves heat away from hot spots, as shown by the arrows 214, in order to spread or dissipate heat about the die 200. The thermally conductive coating 212 also helps remove heat from an exemplary WLP device 200 via convection (as shown via arrows 216). Embodiments of the thermally conductive coating 212 have a substantially uniform thickness of about 20 microns (μm) to about 100 microns (μm).

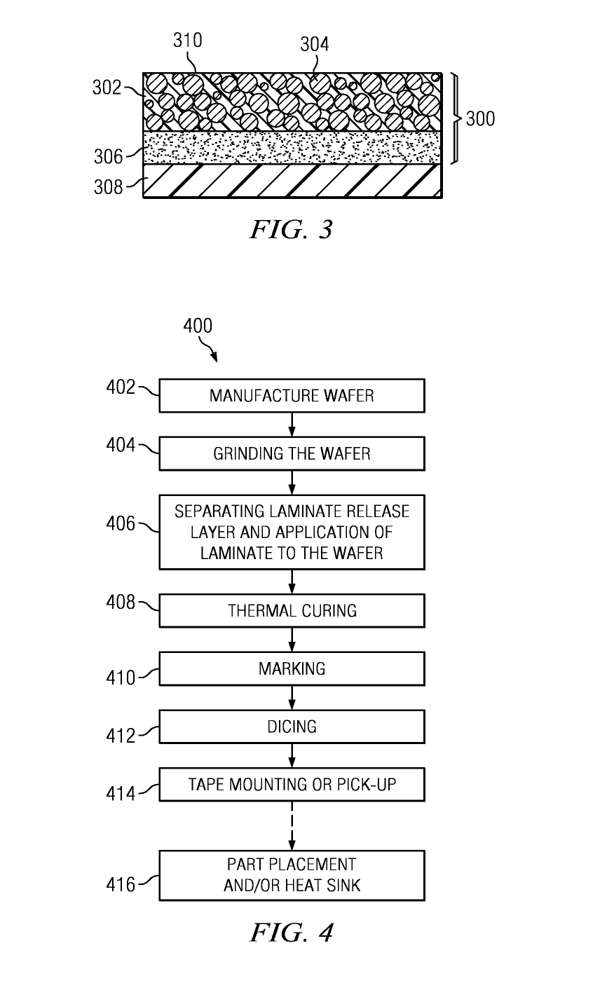

Referring now to FIG. 3, an exemplary thermally conductive coating 300 is depicted. Here a polymeric film or other type of thin film substance 302 has thermally conductive fillers 304 embedded or dispersed within the film layer 302. Thermally conductive fillers 304 that may be dispersed within an exemplary film layer may include silver (Ag), aluminum (Al), aluminum oxide (Al₂O₃) or copper (Cu). Other thermally conductive fillers that aid thermal conduction through a film may also be utilized. The filler particles 304 may vary in size from less than a micron to about 15 microns long. In some embodiments, the film substance 302 may comprise a thin metallic film, woven or latticed thermally conductive fibers, non-woven thermally conductive fibers or malleable thermally conductive elements.

An adhesive layer 306 is next to and against one side of the thermally conductive film layer 302. The adhesive layer 306 also comprises filler particles that are thermally conductive (not specifically shown). The filler particles within the adhesive layer may comprise one or more of the same filler particles, fibers or other thermally conductive items or elements found within the film layer 302. The adhesive layer is used initially to attach the film layer 302 to the back side surface of a wafer, which comprises a plurality die-circuit segments. Once attached, a curing process takes place that cures the adhesive 306 such that the film layer 302 is firmly bonded against the back side 210 of a die 202. When cured, some embodiments' thermally conductive particles, fibers or other elements provide a thermally conductive connection between the back side surface 210 and the top side 310 of the thermally conductive coating 212.

In some thermally conductive coating embodiments, a release layer 308 covers the adhesive layer 306. The release layer 308 is peeled away or peeled off the film layer/adhesive layer combination during the manufacturing process prior to applying the thermally conductive coating 300 (film layer 302 and adhesive layer 306) to the back side 210 of a die 202. In exemplary embodiments, the film layer 302 may have a thickness of from about 20 μm to about 100 μm. In the manufacturing process, exemplary thermally conductive coating 300 may be provided in continuous rolls.

Exemplary thermally conductive coatings will provide a thermal conductivity in the range of 5 to about 50 watts per meter Kelvin. In some embodiments, the thermally conductive coating, when cured, can have a thermally conductive rating as high as about 100 watts per meter Kelvin. The thermally conductive coating 300, which acts as a thermal interface material and has a high thermal conductivity, facilitates the heat dissipation from a WLP package by spreading heat away from local hot spots as well as transferring heat from the silicon layer 202 to a heat spreader or heat-sink that is attached to the top side 310 of the thermally conductive coating. Embodiments of exemplary thermally conductive coatings 300, being sputtered, sprayed, a thin film, a laminate, or with or without an adhesive layer, will have or add thickness to exemplary embodiments of the invention. Such exemplary thermally conductive coatings 300 may have or add a thickness of about 20 microns (μm) to about 100 microns (μm) of thickness to embodiments of the invention.

As mentioned above, in various embodiments of the invention, the thermally conductive coating may comprise a woven material having fibers that are either coated with thermally conductive material or having fibers that have thermally conductive particles colloidally suspended and/or touching each other in the fiber material. Additionally, a woven or lattice of thermally conductive strands may be embedded within the film layer 302 along with or instead of the filler particles 304. The varying embodiments of the thermally conductive coating add structural strength and integrity to the silicon wafer to which it is applied. The exemplary thermally conductive coating or layer 300 will aid in adding integrity by deterring warpage of the silicon wafer and/or the resulting individual dies during the wafer dicing process as well as during each dies operation when installed and/or operating on a PC card. During the manufacturing of the exemplary silicon wafers the back side of the wafer is polished and ground in order to decrease the overall thickness of the resulting WLP packages. Furthermore, WLP packages are increasing in dimensional size as they incorporate larger and more complex circuitry. Embodiments of the invention, which include thermally conductive coatings on the back side of a silicon wafer or die, reinforce the resulting wafer and/or die against warpage and mechanically strengthen the resulting WLP package while improving its overall thermal performance.

The film layer 302, after the adhesive and/or film layer 302 has been cured, may retain some plasticity in that it may conform to or accept indentions from an adjacent surface being pressed against it. The adhesive layer 302 of some embodiments is thus adaptable to conform to an impression of an item pressed against or embedded onto the top side of the thermal conductive coating 310. For example, a heat sink or heat spreader may be pressed against the top surface of the thermally conductive coating 310. In response to a heat sink or spreader being pressed thereon, embodiments of the film layer 302 may conform and indent to a substantially flat, slightly patterned or slightly irregular surface pressed against it so that air bubbles or gaps may be removed and a substantially continuous surface to surface contact exists between the heat sink's bottom surface and the upper surface of the thermally conductive coating 310 in order to maximize thermal conduction. By being an impressionable, compliant, plastic or conformable material, the thermal resistance between the die and a heat sink or heat spreader device may be further minimized in embodiments of the invention.

Referring now to FIG. 4, a method of manufacturing 400 an exemplary WLP package with a thermally conductive coating is depicted. At step 402 a wafer is manufactured. When an exemplary wafer is manufactured for a WLP package, the wafer may include a few to more than 1000 die areas that are each intended to be individual WLP device packages. The manufactured wafer will have a back side surface that is substantially silicon. The exemplary manufactured wafer will also have a front side or active side surface, which may have embedded electronic circuitry, various epoxy and/or metal layers of material and solder balls thereon. At step 404, the back side surface of the silicon wafer may be ground or polished in order to decrease the thickness dimension of the overall silicon wafer. The wafer is ground to a desired thickness via one or more different grinding wheels or polishing wheels that may have different levels of coarseness in order to remove silicon material in a substantially uniform fashion from the back side of the wafer until the wafer is ground to a desired or predetermined thickness.

At step 406, an exemplary thermally conductive coating 300 may be unrolled from, for example, a roll and/or cut to the size of the wafer's back side surface. If there is a release layer 308, it is removed from the thermally conductive coating 300 and the thermally conductive coating 300 is placed on the back side of the wafer such that the adhesive layer is applied to and adheres to the back side surface of the wafer. In some embodiments, the thermally conductive coating 300 is applied to the back side of the wafer and then the excess thermally conductive coating is removed or cut away from the side edges of the wafer. The adhesive layer of the thermally conductive coating holds the thermally conductive coating in place on the back side of the wafer during this step of the manufacturing process. In some embodiments, a thermally conductive coating is sprayed, sputtered or coated onto the backside of the wafer. In such embodiments, the thermally conductive coating is a colloidal mixture of thermally conductive elements and an epoxy, polymer, silicon, ink or other fluid material that suspends the thermally conductive elements therein.

At step 408, the thermally conductive coating 300 is cured on and/or to the back side of the wafer. The curing process may be a thermal process wherein the adhesive layer 306 hardens somewhat such that removal of the thermally conductive coating 300 from the back side of the silicon wafer is difficult. In one embodiment, the curing process may take place at 150 to 200 degrees for a predetermined amount of time that ranges from a half hour to about an hour and a half. In other embodiments, the curing process may be performed using ultraviolet or other wavelengths of light. In yet other embodiments of the invention, the curing process may occur as an evaporative or chemical process wherein the thermally conductive coating goes through a chemical/molecular change during the curing process. Additionally, the curing process strengthens the integrity of the overall wafer and/or an individual dies contained therein. The thermally conductive fillers, lattice, or woven material within the thermally conductive coating provide unexpected advantages of not only establishing thermally conductivity through the coating, but also increased integrity of the resulting wafer and individual WLP devices by adding additional stiffness and mechanically-static strength.

At step 410 the top side 300 of thermally conductive coating 300 may be marked via a printing, ink jet, laser marking, etching or other marking technique in order to place a part number or other pertinent information on the top side 310 of the thermally conductive coating 300.

At step 410, an exemplary wafer may be mounted onto a frame and secured so as to be prepared for dicing. The dicing process involves cutting the silicon wafer into individual exemplary WLP parts. Each exemplary WLP part comprises a die with its active side surface. The die also has a back side or inactive surface having a thermally conductive coating substantially covering the back side. The resulting WLP part will have been manufactured via a wafer level manufacturing process rather than the individual die or unit level manufacturing process of prior art flip-chip devices. In exemplary embodiments, the singulation or dicing of the dies from the wafer effectively provide a resulting exemplary embodiment by the exemplary process.

At step 414, the individual exemplary WLP dies may be picked and placed onto an adhesive side of tape reels, which may be utilized in pick and place machines utilized at step 416 wherein exemplary WLP parts may be picked from the tape reels and placed on to a PC board 208 as shown in FIG. 2. In some embodiments, step 414 or step 416 may further include adding a heat sink or heat spreader to the top surface 310 of the exemplary WLP's thermally conductive coating. The heat sink may be pressed or adhered to the top surface of the thermally conductive coating using an adhesive, an ultrasonic welding/melting process that effectively melts the top side of the thermally conductive coating to the bottom of a heat sink. In other embodiments, the bottom surface of the heat sink may be preheated to a temperature that will partially melt the thermally conductive layer 300 to uncover thermally conductive particles for direct contact with the heat sink and to hold the heat sink in place upon cooling. In some embodiments, the heat sink or heat spreader may be applied on top of the thermally conductive layer on the wafer prior to singulation.

A resulting exemplary WLP device provides a WLP device with a thermally conductive coating (WLP w/TCC) that is competitive with the heat dissipation abilities of prior art flip-chip devices that dissipate or thermally conduct heat away from a silicon die. An advantage of an exemplary embodiment is that additional manufacturing steps are not required to incorporate the thermally conductive coating (TCC) layer or coating onto the back side of an exemplary WLP w/TCC device. The result being a significantly less expensive manufacturing method that produces a thermally conductive silicon die at a wafer level rather than at a die or unit level. Since thousands of dies may be cut out of a single wafer, the manufacturing steps, time and manufacturing costs associated with an exemplary WLP w/TCC are significantly decreased from prior device manufacturing processes.

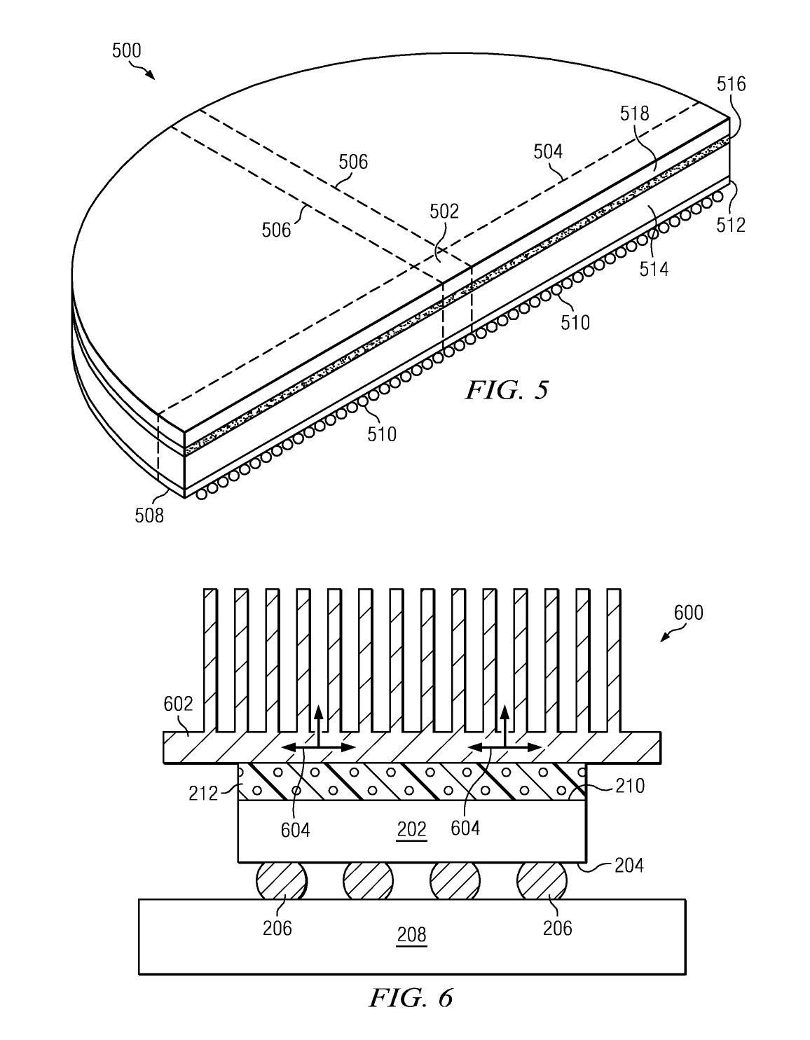

FIG. 5 is a cross-sectional view of an exemplary wafer 500 in accordance with an embodiment of the invention. An individual WLP device 502 has its profile indicated by the row cut lines 504 and column cut lines 506. The resulting exemplary WLP package 502 is singulated from a plurality of other WLP devices manufactured on the exemplary wafer 500. On the front side or active side or active side 508 of an exemplary manufactured wafer 500, there may be an array of solder balls 510 that are attached to the active side 508 during the wafer manufacturing process. Underneath the solder balls 510 is active circuitry, which may include the transistors, dielectric layers, RDL layers, passivation layers and other items associated with the active side 508 of an exemplary manufactured wafer 500. Underneath the active layer portion 512 is the silicon layer 514. The silicon layer, in some embodiments, is the thickest portion of an exemplary manufactured wafer 500 or an exemplary WLP device 502. Moving toward the back side of the silicon layer 514 is the cured adhesive layer or coating 516, which covers the back side of the silicon wafer layer 514. The cured adhesive layer or coating 516 contains thermally conductive fillers such as silver, aluminum, aluminum oxide or copper particles or fibers. On the top or back side surface of the manufactured exemplary wafer 500 or the WLP device 502 is the exemplary thermally conductive coating 518. The exemplary thermally conductive coating 518 may comprise a polymeric film with silica fillers and further include thermally conductive particles of silver, aluminum, aluminum oxide or copper. The thermally conductive coating 518 may comprise a lattice, woven or unwoven structure of thermally conductive material. Furthermore, in some embodiments, the thermally conductive coating may comprise a thin metallic film of aluminum, aluminum oxide, copper or another substantially soft, impressionable, compliant or malleable metal that will aid in the removal or thermal conductivity of heat away from the silicon layer of an exemplary WLP device. Some exemplary thermally conductive coatings, when cured or when its associated adhesive is cured, remain soft, impressionable, compliant or plastic enough to conform to an impression of an item pressed against or embedded onto the surface of the thermally conductive coating. Such an item may be a bottom surface of a heat sink or heat spreader device. Exemplary thermally conductive coatings 518 (including or not including adhesive 516) have an overall substantially uniform thickness (and in some embodiments a non-uniform thickness) in the range of about 20 microns to about 100 microns.

Referring still to FIG. 5, when the exemplary manufactured wafer 500 is cut along the row cut lines 504 and column cut lines 506, a singulated exemplary WLP device 502 results. An exemplary singulated WLP device 502 may be a complete WLP device having solder balls on its active side so that it may be placed and attached to a printed circuit board while including an integrated thermally conductive coating on its inactive side that will aid in thermally dissipating heat from an exemplary WLP package (rather than insulate a WLP package) without a need for additional manufacturing steps, costs, or time. Some exemplary WLP devices may include a heat spreader or heat sink on top of the thermally conductive coating when singulated.

FIG. 6 depicts an exemplary WLP 600 having a heat sink 602 attached or integrated onto the top side of the thermally conductive coating. Here an exemplary WLP package with a heat sink installed thereon 600 is attached to a PC board 208 via a plurality of solder balls 206. The solder balls 206 are mechanically, metallically and electrically attached and connected to the active side 204 of the exemplary WLP package with heat sink 600. The WLPs active side 204 comprises transistors, passivation layers, RDL layers, epoxy layers and perhaps other layers that establish the active circuit side of the WLP device with heat sink 600. The die 202, which is made substantially of silicon, has an inactive or back side surface 210 to which a thermally conductive coating 212 is attached. Thermally conductive coating 212 may be a polymeric film or other film substrate that incorporates thermally conductive particles, fibers, lattice, woven or unwoven structures that not only strengthen and provide additional structural integrity to an exemplary WLP package with heat sink 600, but also thermally conduct heat from the back side 210 of the die 202 toward the heat sink 602, wherein the heat can be dissipated away from hot spots on the die and into the ambient air about the heat sink as shown by the arrows 604. The thermally conductive coating 212 is sandwiched between a bottom surface of the heat sink 602 and the back side surface of the die 210 such that the thermally conductive coating substantially conforms in a ductile, plastic, malleable, or pliable yielding manner to substantially conform to any bumps, ridges or edges on the bottom surface of the heat sink that is pressed into, pressed against, embedded and/or adhered to the thermally conductive coating 212. The thermally conductive coating may establish multiple thermal circuits between the bottom surface of the heat sink 604 and the back side surface of the die 210.

To date, heat sinks and heat spreaders are not being incorporated onto or integrated with the inactive or back side of WLP devices. Therefore, embodiments discussed herein advance the thermal dissipation capabilities of exemplary WLP packages to operate at higher continuous wattage ratings than prior WLP packages have been able to operate at. For example, exemplary WLP devices are designed to dissipate heat in a manner such that they may be rated to operate at a greater than 20 watt heat dissipation rating. Embodiments of the invention may be rated from about 20 watts to about 50 watts of continuous heat dissipation. Some embodiments may be rated at up to about 90 watts. Since WLP devices are being utilized in smaller and smaller consumer oriented devices such as mobile phones, mobile terminals, GPS devices and various other small portable hand held devices, it is advantageous to decrease the size of a device package from a flip-chip device down to an exemplary WLP device and still be able to dissipate enough heat such that higher power circuitry can be incorporated into the exemplary WLP device.

By providing an exemplary WLP w/TCC, the size of wafer level packages can grow from 7×7 ball array WLP devices to 20×20 ball array WLP devices or larger while maintaining both the structural strength of the resulting device and supporting higher power circuitry (from 20 to about 90 watts).

It will be appreciated by those skilled in the art having the benefit of this disclosure that this wafer level packaging with integrated heat dissipation provides a WLP with improved structural strength and higher power capabilities without a significant increase in manufacturing costs. It should be understood that the drawings and detailed description herein are to be regarded in an illustrative rather than a restrictive manner, and are not intended to be limiting to the particular forms and examples disclosed. On the contrary, included are any further modifications, changes, rearrangements, substitutions, alternatives, design choices, and embodiments apparent to those of ordinary skill in the art, without departing from the spirit and scope hereof, as defined by the following claims. Thus, it is intended that the following claims be interpreted to embrace all such further modifications, changes, rearrangements, substitutions, alternatives, design choices, and embodiments.

What is claimed is:

1. A method of manufacturing a heat dissipating wafer level package, the method comprising:
applying a thermally conductive coating on a back surface of a wafer, the wafer comprising a plurality of wafer level package device sections; and
curing the thermally conductive coating.

2. The method of claim 1, wherein applying the thermally conductive coating further comprises applying a laminate to the back surface, the laminate comprising:
a thermally conductive adhesive layer; and
a thermally conductive film layer.

3. The method of claim 1, wherein applying the thermally conductive coating further comprises spraying the thermally conductive coating on the back surface.

4. The method of claim 3, wherein applying the thermally conductive coating further comprises applying a first charge to the wafer adapted to attract the thermally conductive coating.

5. The method of claim 1, wherein curing further comprises applying heat to the thermally conductive coating.

6. The method of claim 1, wherein curing further comprises applying light to the thermally conductive coating.

7. The method of claim 1, further comprising dicing the wafer into the plurality of wafer level package device sections, each wafer level package device section having a top side.

8. The method of claim 7, further comprising attaching a heat spreader to the top side of a wafer level package device section.

9. The method of claim 1, wherein the cured thermally conductive coating is adapted to conform to an impression of an item embedded on a surface of the cured thermally conductive coating.

10. The method of claim 9, wherein the item is a heat sink.

11. A Wafer Level Package (WLP) device comprising:
a WLP die, the WLP die having a circuit side and a back side;
a coating covering the backside, the coating comprising a thermally conductive filler dispersed within the coating.

12. The WLP device of claim 11, wherein the coating comprises a film that comprises the thermally conductive filler.

13. The WLP device of claim 11 wherein the coating comprises an adhesive that comprises the thermally conductive filler.

14. The WLP device of claim 11, wherein the thermally conductive filler is organized in a mesh or lattice configuration.

15. The WLP device of 11, wherein the thermally conductive coating is an impressionably compliant thermally conductive coating adapted to conform to a surface of an item pressed thereon.

16. A Wafer Level Package (WLP) device comprising:
a WLP die, the WLP die having a circuit side and a back side;
a coating covering the backside, the coating comprising a thermally conductive filler dispersed within the coating; and
a heat sink having a first surface engaged with the coating.

17. The WLP device of claim 16, wherein the coating is adapted to conform to the first surface.

18. The WLP device of claim 16, wherein the coating comprises a film that comprises the thermally conductive filler.

19. The WLP device of claim 16, wherein the coating comprises an adhesive that comprises the thermally conductive filler.
